(19) United States
(12) Patent Application Publication
(10) Pub. No.: US 2023/0018396 A1
(43) Pub. Date: Jan. 19, 2023

(54) CIP PACKAGE

(71) Applicant: HARUMOTO TECHNOLOGY (SHEN ZHEN) CO., LTD., Shenzhen (CN)

(72) Inventor: Ching-Chuan Kung, Taipei City (TW)

(21) Appl. No.: 17/866,062

(22) Filed: Jul. 15, 2022

(30) Foreign Application Priority Data
Jul. 16, 2021 (TW) 110126313

(51) Int. Cl. H01L 23/66; H01Q 1/22; G01R 31/28

(52) U.S. Cl. CPC H01L 23/66; H01Q 1/2283; G01R 31/2896; H01L 2223/6611; H01L 2223/6677; H01R 24/40

(57) ABSTRACT

An electronic device and a CIP (connector-in-package) package used therein. The CIP package can includes a semiconductor chip, an RF connector, and a carrier substrate. The carrier substrate is for carrying the semiconductor chip and the RF connector and electrically connected to the semiconductor chip and the RF connector to allow the semiconductor chip to transmit RF signal through the RF connector.

### CROSS-REFERENCE TO RELATED APPLICATIONS

This application claims the priority of Republic of China Patent Application No. 110126313 filed on Jul. 16, 2021, in the State Intellectual Property Office of the R.O.C., the disclosure of which is incorporated herein by reference.

### BACKGROUND OF THE INVENTION

### Field of the Invention

The present invention relates to an electronic device, and more particularly, the present invention relates to an electronic device and a CIP (connector-in-package) package thereof.

### Descriptions of the Related Art

In an electronic device, a chip package is usually mounted at a predetermined location on a PCB (printed circuit board) to form a PCBA (printed circuit board assembly) architecture to work integrally. Innovation of wireless communication technology requires an antenna module to co-operate with the chip package for some operations in order to form a wire-less signal transceiver system for transmitting RF (radio frequency) signals. As shown in a conventional PCBA architecture of FIG. 1, a chip package 21 would send RF signals to an antenna module 23 or receive RF signals from the antenna module 23 through internal wiring of a PCB 22. However, due to limitations on material, wiring design, wiring loss, manufacture cost and so on for the PCB, internal wiring of the PCB cannot have a breakthrough to effectively transmit high frequency RF signals, making the conventional PCBA architecture not yet suitable for transmission of millimeter-wave-level RF signals, not to mention meeting transmission requirements for millimeter-wave-level high frequency RF signals in 5G communication generation.

In order to solve the above problem of the PCBA architecture not able to effectively transmit high frequency RF signals, AIP (antenna-in-package) package technology has been innovated. As shown in FIG. 2, a current AIP package includes an antenna module 33 (such as antenna patch) mounted on a chip package 31, wherein the chip package 31 can directly be fanned out to the antenna module 33 to allow the antenna module 33 to send high frequency RF signals. Further, the antenna module 33 can be fanned in to the chip package 31 to allow the chip package 31 to receive high frequency RF signals directly from the antenna module 33. The AIP package thus does not use internal wiring of a PCB for RF signal transmission, thereby providing a solution to the problem of the conventional PCBA architecture failing in transmission of millimeter-wave-level RF signals.

The AIP package beneficially avoids the use of a PCB for RF signal transmission, but causes another issue from its only option of placing the antenna module on the chip package. This undesirably makes configuration of the antenna module limited by the chip package in terms of location, size, direction and functionality. The AIP package is thus not able to flexibly meet all requirements in application.

Therefore, how to solve the above problems that the PCBA architecture cannot effectively transmit millimeter-wave-level high frequency RF signals and the AIP package has limited configuration of the antenna module on the chip package, has become an important task in the art.

### SUMMARY OF THE INVENTION

In view of the above drawbacks in the prior art, the present invention is to provide a CIP package. The CIP package includes a semiconductor chip; an RF connector including an RF signal port; and a carrier substrate for carrying the semiconductor chip and the RF connector. The carrier substrate includes an RF transmission circuit electrically connected to the semiconductor chip and the RF connector to allow the semiconductor chip to transmit an RF signal through the RF signal port.

Preferably, in the CIP package said above, the RF signal is a millimeter wave signal.

Furthermore, the present invention is to provide an electronic device including: a CIP package and a processing module. The CIP package includes a semiconductor chip; an RF connector including an RF signal port; and a carrier substrate for carrying the semiconductor chip and the RF connector. The carrier substrate including an RF transmission circuit electrically connected to the semiconductor chip and the RF connector to allow the semiconductor chip to transmit an RF signal through the RF signal port. The processing module for electrically processing the RF signal, wherein the processing module is electrically connected to the RF connector to allow the RF signal port to send the RF signal to the processing module.

Preferably, in the electronic device said above, the RF signal is a millimeter wave signal.

Preferably, in the electronic device said above, the processing module is an antenna module for sending and receiving the RF signal.

Preferably, in the electronic device said above, the processing module is a test module for testing if the RF signal is normal.

Preferably, in the electronic device said above, the CIP package is located at a first position and the processing module is located at a second position, and the electronic device further includes a coaxial cable having two ends extended to the first position and the second position respectively to be electrically connected to the RF connector and the processing module so as to allow the RF signal to be transmitted between the first position and the second position through the coaxial cable.

In comparison to prior arts, the present invention is to provide an electronic device and a CIP (connector-in-package) package used therein. The CIP package can transmit millimeter-wave-level high frequency RF signals through a RF connector, thereby solving the problem of the conventional PCBA architecture not able to effectively transmit high frequency RF signals. Moreover, a remote processing module (such as antenna module) can be electrically connected to a semiconductor chip in the CIP package by the RF connector, such that the antenna module is no longer limited by a chip package but can be situated at any suitable location other than on the chip package, giving flexibility in designing the antenna module in terms of size, direction and functionality to meet all requirements in application, and thereby solving the problem of the conventional AIP package having restricted applications.

Furthermore, a processing module (such as test module) can be electrically connected to the semiconductor chip in the CIP package by the RF connector to directly test if an RF signal of the semiconductor chip in the CIP package is normal. This advantageously allows the RF signal of the semiconductor chip in the CIP package to be checked directly and effectively.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic diagram of a conventional PCBA architecture including a PCB, a chip package and an antenna module.

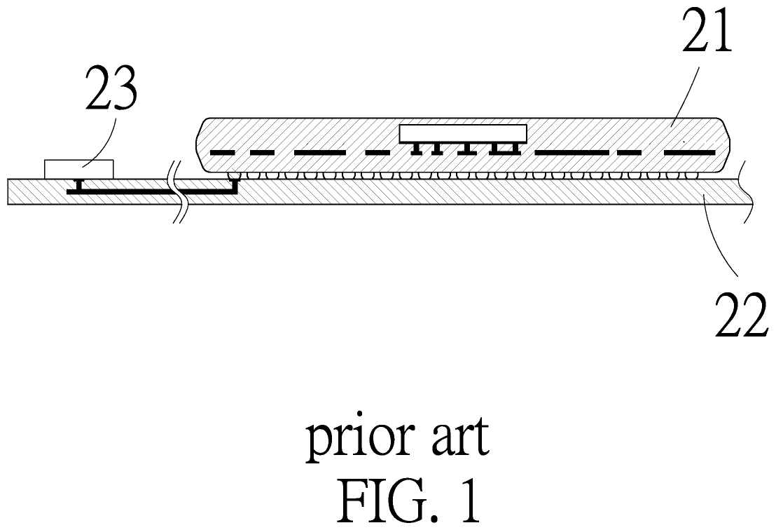

FIG. 2 is a schematic diagram showing a usage status of a conventional AIP package.

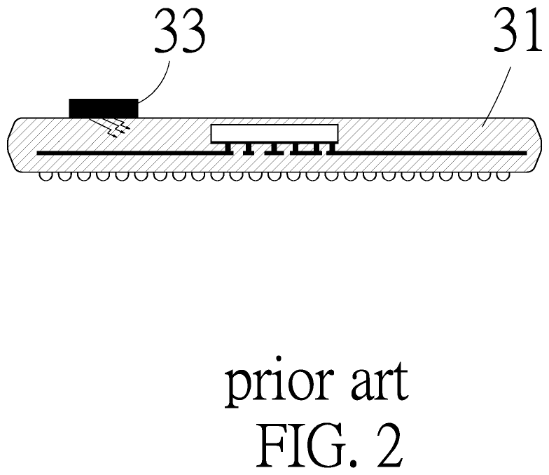

FIG. 3 is a schematic diagram showing usage status of a CIP package according to the present invention.

FIG. 4 is a schematic diagram showing usage status of a CIP package according to the present invention.

FIG. 5 is a schematic diagram showing usage status of a CIP package according to the present invention.

FIG. 6 is a schematic diagram showing usage status of a CIP package according to the present invention.

FIG. 7 is a schematic diagram showing usage status of a CIP package according to the present invention.

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

The following content will be combined with the drawings to illustrate the technical content of the present invention through specific embodiments. Those familiar with the technology can easily understand the other advantages and effects of the present invention from the content discussed in this specification. This invention can also be implemented or applied by other different specific embodiments. Various details in this specification can also be modified and changed based on different view-points and inventions without departing from the spirit of this invention. Especially, the quantitative relationship, proportional relationship, and relative position of each component in the drawings are only exemplary, and do not represent the actual implementation of this invention.

The present invention provides an electronic device and a CIP package thereof CIP package is formed by directly placing for example an RF I/O connector (hereinafter “RF connector”), which can transmit millimeter-wave-level high frequency RF signals, in a semiconductor chip package, which means CIP package is a chip package with an internal RF connector. In the present invention, the CIP package includes a semiconductor chip, an RF connector and a carrier substrate, wherein the carrier substrate is electrically connected to the semiconductor chip and the RF connector, and thus the semiconductor chip can send RF signals to the RF connector through the carrier substrate. Then, the RF connector can directly send the RF signals to a remote antenna module through a different way of connection so as to form a wireless signal transceiver system for transmitting millimeter-wave-level high frequency RF signals. In such a case, the antenna module is no longer limited by a chip package but can be situated at any suitable location other than on the chip package, giving flexibility in designing the antenna module in terms of size, direction and functionality to meet all requirements in application, and thereby solving the problem of the conventional AIP package having restricted applications. Moreover, the use of the RF connector to transmit millimeter-wave-level high frequency RF signals can completely resolve the problem of the conventional PCBA architecture failing to effectively transmit high frequency RF signals.

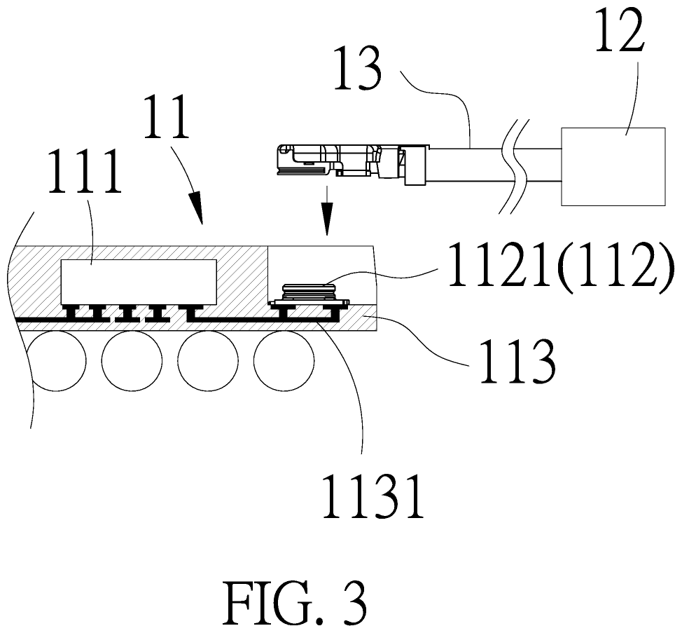

Technical features of the electronic device and the CIP package thereof according to the present invention are described as follows with referent to embodiments shown in FIGS. 3 to 7.

As shown in FIGS. 3 to 7, the electronic device 1 of the present invention includes a CIP package 11 and a processing module 12. The CIP package 11 includes a semiconductor chip 111, an RF connector 112 and a carrier substrate 113. The RF connector 112 can be RF coaxial connector, RF BTB (board-to-board) connector or any other connectors as desired, which is for transmitting millimeter-wave-level high frequency RF signals. The RF connector 112 includes an RF signal port 1121 such as RF signal transmission I/O port.

Moreover, the carrier substrate 113 is for example a leadframe for carrying the semiconductor chip 111 and the RF connector 112, and includes an RF transmission circuit 1131 for being electrically connected to the semiconductor chip 111 and the RF connector 112, such that the semiconductor chip 111 can transmit RF signals (such as millimeter-wave-level high frequency RF signals) through the RF signal port 1121 without the need of a PCB. The processing module 12 is electrically connected to the RF connector 112, and the RF signal port 1121 can send the RF signals to the processing module 12 where the RF signals can be processed electrically.

As shown in FIG. 3, the electronic device 1 includes a coaxial cable 13, and the processing module 12 is an antenna module for sending and receiving the RF signals, wherein the antenna module is electrically connected to the RF connector 112 by the coaxial cable 13. As the coaxial cable 13 has much less RF signal wire transmission loss than a PCB, the antenna module and the RF connector 112 are capable of transmitting millimeter-wave-level high frequency RF signals through the coaxial cable 13. The antenna module thus can have very flexible configuration, not limited by the chip package, and can be placed at any suitable position in the electronic device rather than on the chip package.

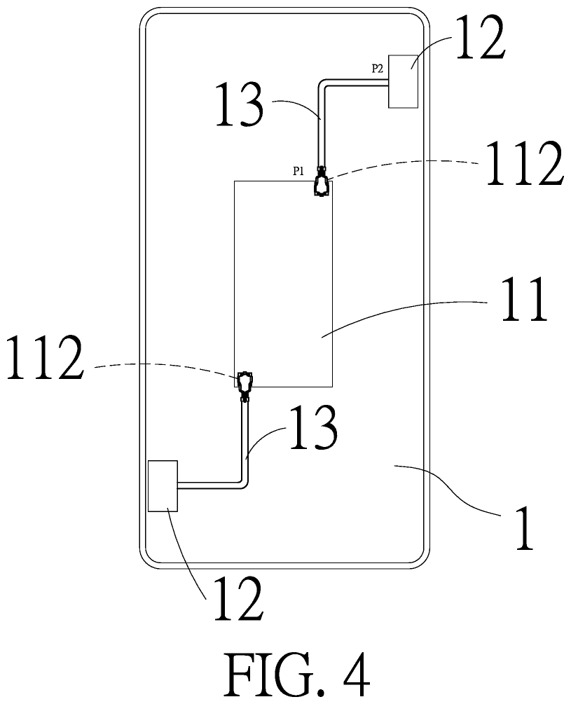

As shown in FIG. 4, the CIP package 11 is located at a first position P1, and the processing module 12 is an antenna module located at a second position P2. The coaxial cable 13 has two ends extended to the first position P1 and the second position P2 respectively to be electrically connected to the RF connector 112 and the antenna module so as to allow millimeter-wave-level high frequency RF signals to be transmitted between the first position P1 and the second position P2 through the coaxial cable 13, such that the CIP package 11 and the antenna module can have different locations. In the present invention, the antenna module is flexibly placed at any suitable position in the electronic device and does not have limitations on size, direction and functionality, thereby meeting application requirements as desired, unlike the conventional AIP package having restricted applications.

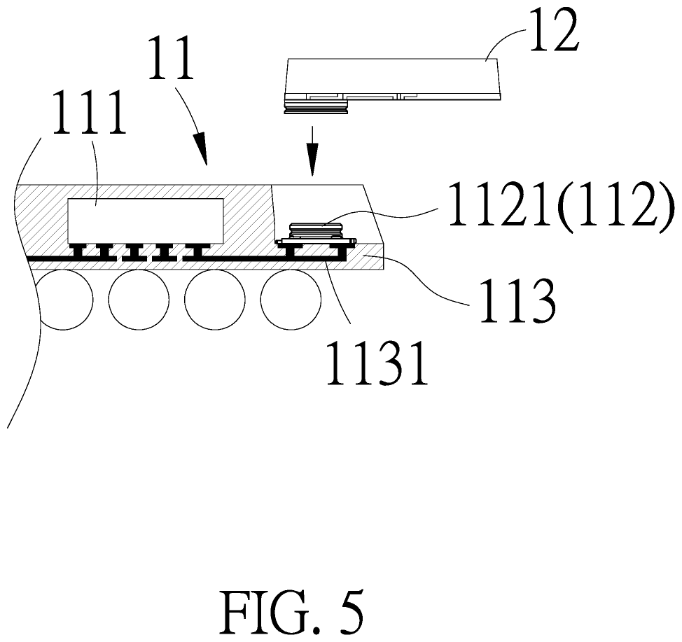

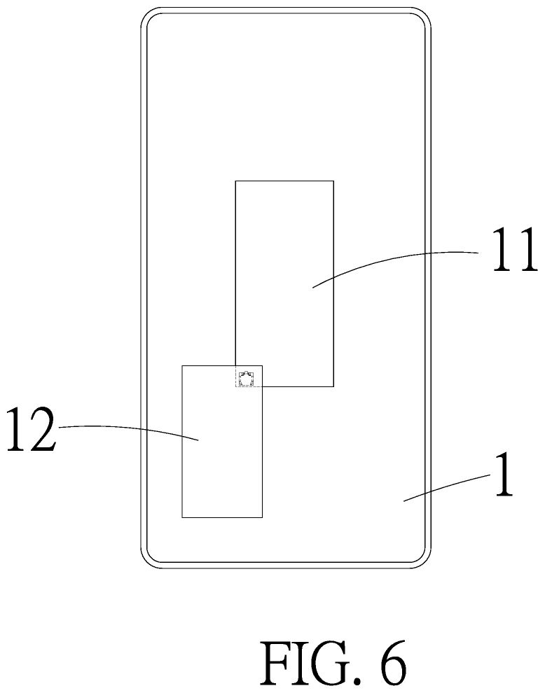

As shown in FIGS. 5 to 6, the processing module 12 is an antenna module, which is separate from the CIP package 11. The antenna module can directly be electrically connected to the RF connector 112 of the CIP package 11. In such a case, the antenna module and the CIP package 11 can separately be designed, manufactured and maintained, making the antenna module flexible in size, direction and functionality to meet desirable application requirements, while solving the problem of the conventional AIP package having restricted applications.

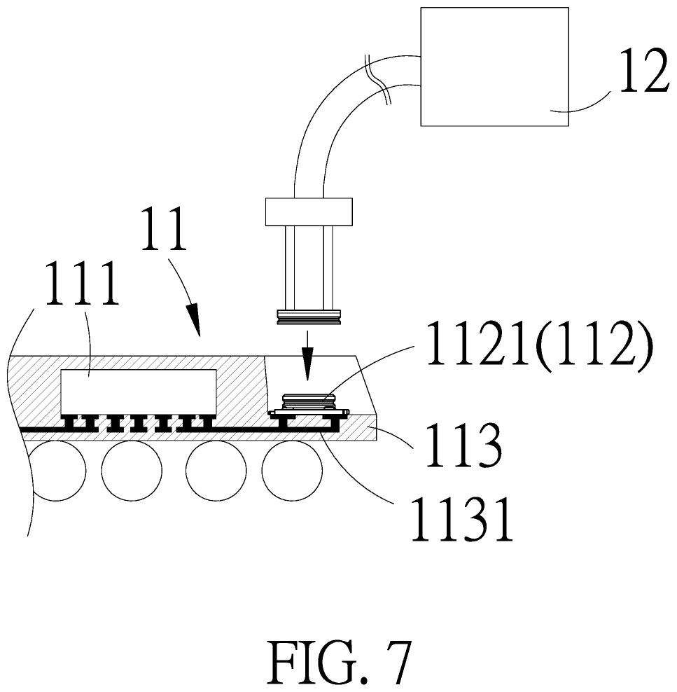

As shown in FIG. 7, the processing module 12 is a test module for testing if an RF signal is normal. The test module has a test probe being electrically connected to the RF connector 112 of the CIP package 11 to read an RF signal in the semiconductor chip and directly check if the RF signal is normal. This provides an effective way of directly testing an RF signal of a semiconductor chip in a chip package desirably and advantageously in the art.

Therefore, the present invention is to provide an electronic device and a CIP (connector-in-package) package used therein. The CIP package can includes a semiconductor chip, an RF connector, and a carrier substrate. The carrier substrate is for carrying the semiconductor chip and the RF connector. The carrier substrate includes an RF transmission circuit electrically connected to the semiconductor chip and the RF connector to allow the semiconductor chip to transmit millimeter-wave-level high frequency RF signal through the RF connector, thereby solving the problem of the conventional PCBA architecture not able to effectively transmit high frequency RF signals.

Moreover, a remote processing module (such as antenna module) can be electrically connected to a semiconductor chip in the CIP package by the RF connector, such that the antenna module is no longer limited by a chip package but can be situated at any suitable location other than on the chip package, giving flexibility in designing the antenna module in terms of size, direction and functionality to meet all requirements in application, and thereby solving the problem of the conventional AIP package having restricted applications.

Furthermore, a processing module (such as test module) can be electrically connected to the semiconductor chip in the CIP package by the RF connector to directly test if an RF signal of the semiconductor chip in the CIP package is normal. This advantageously allows the RF signal of the semiconductor chip in the CIP package to be checked directly and effectively.

The examples above are only illustrative to explain principles and effects of the invention, but not to limit the invention. It will be apparent to those skilled in the art that modifications and variations can be made without departing from the scope of the invention. Therefore, the protection range of the rights of the invention should be as defined by the appended claims.

What is claimed is:

1. A connector-in-package (CIP) package including:
a semiconductor chip;
an radio frequency (RF) connector including an RF signal port; and
a carrier substrate for carrying the semiconductor chip and the RF connector, the carrier substrate including an RF transmission circuit electrically connected to the semiconductor chip and the RF connector to allow the semiconductor chip to transmit an RF signal through the RF signal port.

2. The CIP package according to claim 1, wherein the RF signal is a millimeter wave signal.

3. An electronic device including:
the CIP package according to claim 1; and
a processing module for electrically processing the RF signal, wherein the processing module is electrically connected to the RF connector to allow the RF signal port to send the RF signal to the processing module.

4. The electronic device according to claim 3, wherein the RF signal is a millimeter wave signal.

5. The electronic device according to claim 3, wherein the processing module is an antenna module for sending and receiving the RF signal.

6. The electronic device according to claim 3, wherein the processing module is a test module for testing if the RF signal is normal.

7. The electronic device according to claim 3, wherein the CIP package is located at a first position and the processing module is located at a second position, and the electronic device further includes a coaxial cable having two ends extended to the first position and the second position respectively to be electrically connected to the RF connector and the processing module so as to allow the RF signal to be transmitted between the first position and the second position through the coaxial cable.
